(19) United States
(12) Patent Application Publication
(10) Pub. No.: US 2016/0043335 A1
(43) Pub. Date: Feb. 11, 2016

(54) TRANSPARENT OLED ARCHITECTURAL PARTITION AND METHOD

(71) Applicant: UMM AL-QURA UNIVERSITY, Makkah (SA)

(72) Inventors: Khaled I. Nabil AHMED, Ismailia (EG); Sara Khaled NABIL, Giza (EG)

(73) Assignee: UMM AL-QURA UNIVERSITY, Makkah (SA)

(21) Appl. No.: 14/391,473

(22) PCT Filed: Jul. 29, 2014
(86) PCT No.: PCT/IB2014/001405

§ 371 Date: Oct. 9, 2014

(51) Int. Cl. H01L 51/00; G06F 3/00; G06F 3/041; G08C 17/02; G08C 23/04; G09G 3/32; H01L 27/32; G06F 3/01

(52) U.S. Cl. CPC H01L 51/0097; H01L 27/3225; H01L 27/3244; H01L 27/3276; H01L 27/3234; G06F 3/005; G06F 3/017; G08C 17/02; G08C 23/04; G09G 3/3208; G06F 3/041; H01L 2251/5338; G09G 2354/00; G09G 2380/02; G06F 2203/04102

(57) ABSTRACT

An intelligent architectural display dividing system includes a foldable, retractable partition including a flexible TOLED display screen, which is used when deployed in an interior space. A controllable motor is used to controllably retract and deploy the transitory side of the foldable, retractable partition to change between a folded state and a taut state. A sensor generates a control signal for actuating the motor in response to detecting at least one of a user gesture and reception of a remote control signal. A processor includes circuitry used to respond to the control signal by actuating the motor to automatically retract or deploy the foldable, retractable partition and display a predetermined image from an image source on the flexible TOLED display screen when the foldable, retractable partition is deployed.

### CROSS-REFERENCE TO RELATED APPLICATIONS

The present application contains subject matter related to co-pending U.S. application entitled “OLED multi-use intelligent curtain and method”, having a common inventorship and a common filing date with the present application, the entire contents of which being incorporated herein by reference.

### BACKGROUND

### Description of the Related Art

The “background” description provided herein is for the purpose of generally presenting the context of the disclosure. Work of the presently named inventors, to the extent it is described in this background section, as well as aspects of the description which may not otherwise qualify as prior art at the time of filing, are neither expressly or impliedly admitted as prior art against the present invention.

Transparent Organic light emitting diode (TOLED) displays are displays that can be used in a variety of consumer electronic devices. TOLEDs are conventionally included in commercial electronics on a relatively small scale, such as a display on a smartphone or tablet computer.

### SUMMARY

An intelligent display dividing system includes a foldable, retractable partition including a flexible TOLED display screen that is used by being deployed in an interior space. A controllable motor is used to controllably retract and deploy the translatory side of the foldable, retractable partition so as to controllably change between a folded state and a taut state, the foldable, retractable TOLED being visible from the interior space, when in the taut state. A sensor used to generate a control signal for actuating the motor in response to detecting at least one of a user gesture and reception of a remote control signal; and a processor having circuitry used to respond to the control signal by actuating the motor to automatically retract or deploy the foldable, retractable partition and display a predetermined image from an image source on the flexible TOLED display screen when the foldable, retractable partition is deployed.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1 is a perspective view of a living space that includes both an OLED intelligent display dividing system, and a TOLED (transparent OLED) architectural partition in a household setting;

FIG. 2 is a schematic of an intelligent display dividing system that includes a motor actuated deployment mechanism as well as a catch to make the OLED intelligent display dividing system taut when deployed;

FIG. 3 is a schematic similar to FIG. 2 but also includes fabric panels at opposing sides;

FIG. 4 is an overhead view of a dual intelligent display dividing system that includes two OLED displays facing in opposite directions;

FIG. 5 is a flowchart of a process for determining whether to deploy the intelligent display dividing system as well as detect gestures for operating the intelligent display dividing system;

FIG. 6 is a flowchart of a process used by the intelligent display dividing system for limiting command lists for particular users that were detected by the system;

FIG. 7 is a flowchart of a process for implementing a “virtual window” using an intelligent display dividing system;

FIG. 8 is a flowchart of an intelligent display dividing system used to prompt a user and provide a user with instructions based on scheduled events; and

FIG. 9 is a block diagram of processing circuitry used to implement a controller for the intelligent display dividing system according to the present embodiment.

### DETAILED DESCRIPTION OF THE EMBODIMENTS

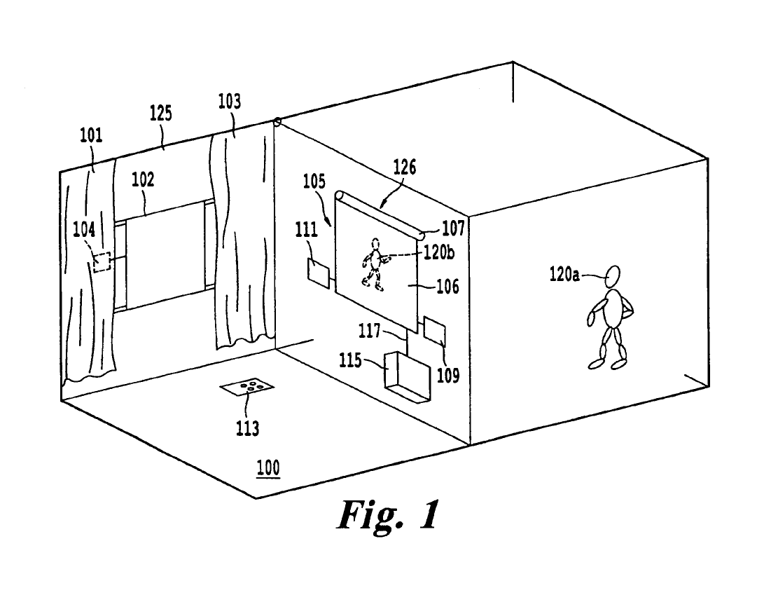

Referring now to the drawings, wherein like reference numerals designate identical or corresponding parts throughout the several views, FIG. 1 is a perspective view of a room 100 that includes an intelligent display dividing system 125 placed against a wall in the room 100, as well as a TOLED architectural partition 126, that divides a space within the room 100.

The intelligent display dividing system 125 includes a left-hand fabric section 101 and a right-hand fabric section 103. Between the left-hand fabric section 101 and the right-hand fabric section 103 is a flexible OLED 102 that is attached there between. The intelligent display dividing system 125 may be deployed as occupying only a portion of the wall within the room 100, or may be displayed when deployed so as to occupy an entirety or a large portion of the wall on which it is deployed in the room 100. In this way, when the flexible OLED 102 is deployed, it provides an interactive curtain that displays an image of desired decorations or a natural scene for example. These realistic views may be 3D (optionally with the user wearing 3D glasses or a 3D display itself). When the intelligent display dividing system is not in use, the flexibility of the fabric sections 101, 103 and the flexible OLED 102 permit the intelligent display dividing system 125 to be drawn closed (manually or through automated motor control). When closed, the intelligent display dividing system 125 may be opened by way of detection of a user performing a gesture or other detectible motion, or by way of an electronic device such as a remote controller 113, dispatching a “deployment” command.

The intelligent display dividing system 125 may include on the flexible OLED 102, as driven by a controller (processing circuitry) 115, with images (still or video) regarding a user's favorite selected scenes, TV, multimedia, providing lighting surface or through a telepresence operation (life-size chat sessions, for example).

However, the intelligent display dividing system 125 may also be used as a “virtual window”, by being provided with an image of an externally pointed camera 104 that captures still or video images from outside of the room 100 such that the images captured on the camera 104 are displayed on the flexible OLED 102. In this way, a user inside the room 100 may have the visual impression of looking through a window, but in reality will really be viewing the image captured by the external camera 104 as displayed on the flexible OLED 102.

A TOLED (transparent OLED) architectural partition 126 includes a transparent OLED partition 105 that is deployed and retracted by a controllable motor 107. The TOLED is transparent such that a user in another room (user 120a) may be visible to a user in room 100 by way of transparency of the TOLED partition 105. This image is shown as a transparent image 120b.

The TOLED architectural partition 126 also includes a sensor 109, a camera 111, and a remote control 113. The sensor 109 is used to detect different human gestures as well as remote control signals. For example, in response to the sensor 109 detecting a human gesture from a user in the room 100, the processor circuitry 115 is activated to either deploy or retract the transparent OLED partition 105. Similarly, the processing circuitry 115 performs predetermined tasks based on different remote control signals as well as different human gestures received. The camera 111 is used to capture an image of a user in the room 100 and cause the processor circuitry 115 to retrieve a command list that is user specific and display it on the transparent OLED partition 105. In this way, when an older user (e.g. an elderly person) for example, enters the room 100 and is detected by the sensor 109 and the camera 111, the TOLED architectural partition 126 causes the processing circuitry 115 to cause the controllable motor 107 to deploy the transparent OLED partition 105 to an appropriate distance based on the height of the detected user, and/or enlarge and increase the font size and the volume respectively for that particular person. Persons within the residence may preregister personal profile features so the processing circuitry can configure the image and content presented on the TOLED 105 to match the preferences of the detected person. These features may include screen height, font size, audio volume, content presented etc.

Transparent OLED architectural partition 126 may be used to divide open spaces with disappearing dynamic lightweight transparent partitions that are dissimilar to fixed heavyweight glass partitions. It may act as an active wall, a foldable TV, or as a display surface of a favorite internal atmosphere by displaying any partition shape, color, and texture. For example, the transparent OLED architectural partition 126 may be used to project an image of a wooden panel or a stone wall. Furthermore, it can also be used as a lighting surface achieving different modes, for example romantic, exciting, or even formal for an office space partition.

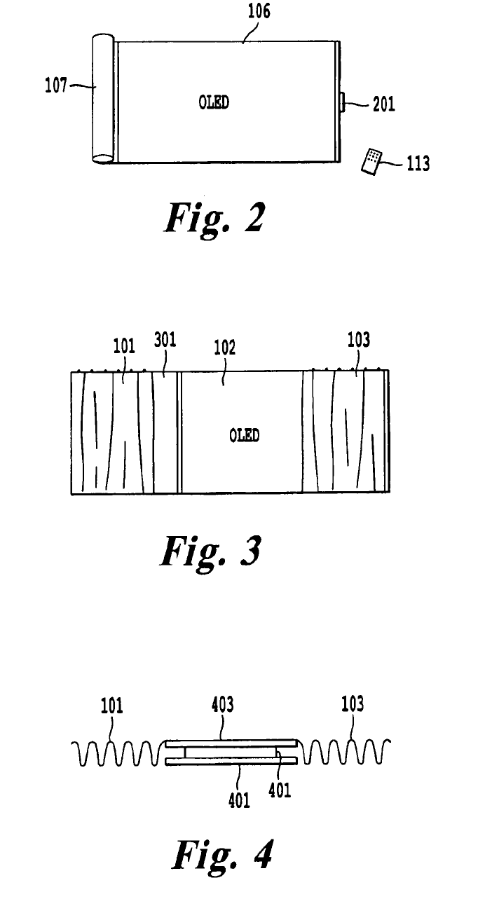

FIG. 2 is a schematic of the TOLED section 126 of the intelligent display dividing system shown in FIG. 1 but in a horizontal orientation. The TOLED section shown in more detail in FIG. 2 includes a catch 201. The catch may be a magnetic catch that is used to pull the TOLED section taut once it is deployed, and/or is controlled to provide different display effects (e.g. ripple effect).

FIG. 3 is similar to FIG. 2 as it shows a more detailed schematic of the intelligent display dividing system 125, including a vertical storage 301 that is used to store the flexible OLED section 102 when not in use.

FIG. 4 is a schematic of an overhead view of the intelligent display dividing system 125 including dual flexible OLED sections 401 and 403, front and back respectively, facing opposite directions. The front and back flexible OLED sections 401 and 403 respectively, are separated by a separator 402 that prevents interference from whatever is being displayed on either of the front and back flexible OLED sections 401 and 403 respectively. In an exemplary implementation, the intelligent display dividing system 125 is used to divide a space such that both the front flexible OLED section and the back flexible OLED sections 401 and 403 respectively, can be used to display different things at the same time in the same space.

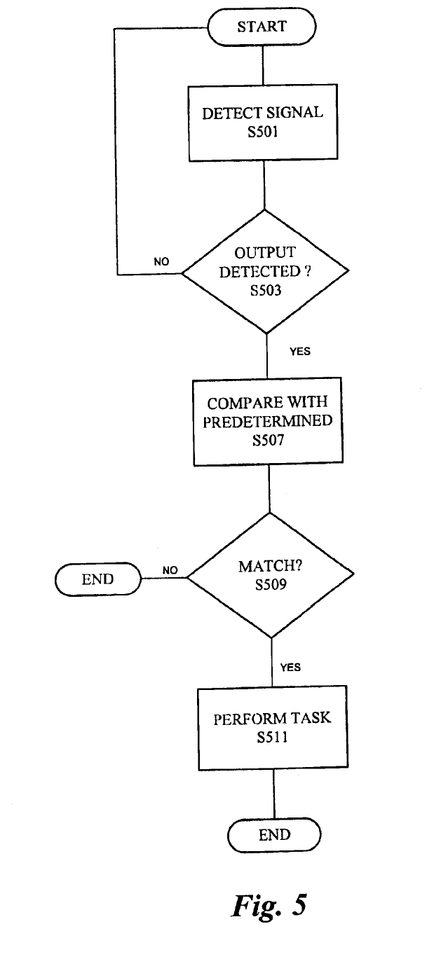

FIG. 5 is a flowchart 500 for an embodiment using the sensor 109 shown previously in FIG. 1 utilizing the system described herein. At step S501, which is a ready state, the system waits for a sensor to detect a human gesture or a remote control signal. At step S503, a controller determines whether or not a signal has been detected. If not, then the system returns to the ready state. However, if an output was detected, the controller proceeds to step S507 to compare the detected signal with a set of predetermined signals saved in memory. Once the controller determines that the signal matches one of the predetermined signals at step S509, it proceeds to perform a predetermined associated task with the signal received at step S511.

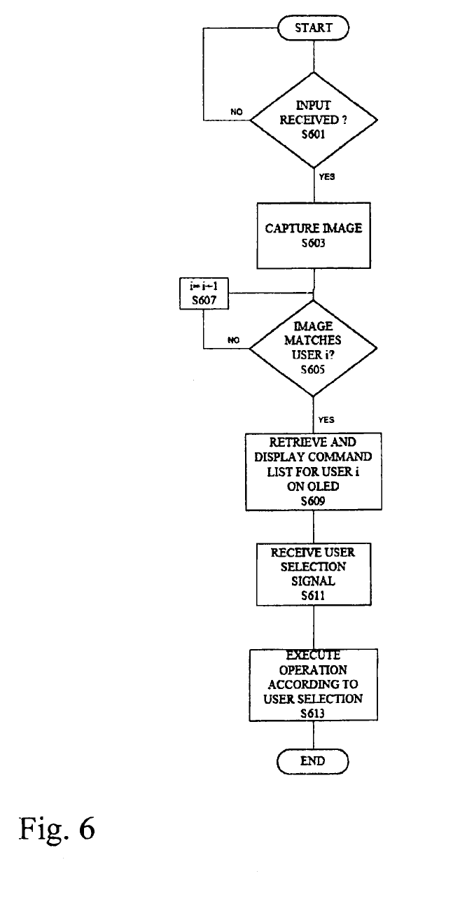

FIG. 6 is a flowchart 600 for an embodiment using the imaging device or the camera shown in FIG. 1. Step S601 is a waiting step where the system waits for an input to be received. Once an input has been received, the process proceeds to step S603 where a controller causes the imaging device to capture an image. At step S605 the controller is used to match the captured image with one of the multiple predetermined images saved in memory. If the controller fails at matching the images, then it continues looking at step S607. However, if it succeeds at finding a match, then the process proceeds to step S609 where the controller is programmed to retrieve an associated command list that is match specific and display it on the OLED flexible display section 102. At step S611 the system waits to receive a selection signal from the user. Once a selection signal has been received, the process proceeds to step S613 where the controller executes the selected option according to the input received.

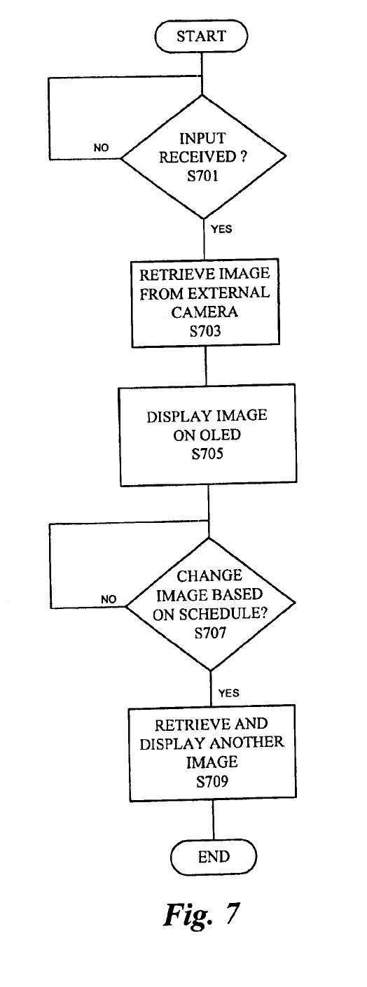

FIG. 7 is an embodiment of the intelligent display dividing system and the TOLED architectural display wherein an external camera may be used to implement a virtual window. FIG. 7 is a flowchart that describes an algorithm used to provide the user with the ability of looking outside without a window as described herein. Step S701 is a waiting state where the system waits for the receipt of an input. If no input was received then the system continues to wait. However if an input was received, the system proceeds to step S703, where the controller is used to retrieve image data, which could be an image or a video from an external camera. At step S705 the controller displays the retrieved image from the external camera on the OLED. The system then proceeds to step S707 where it awaits the receipt of an input to change the display. If no input is received, then the controller will continue to display the image data provided from the external camera. However, if there was an input for an image change, the system proceeds to step S709 at which point the controller retrieves and displays another image or content based on the received input.

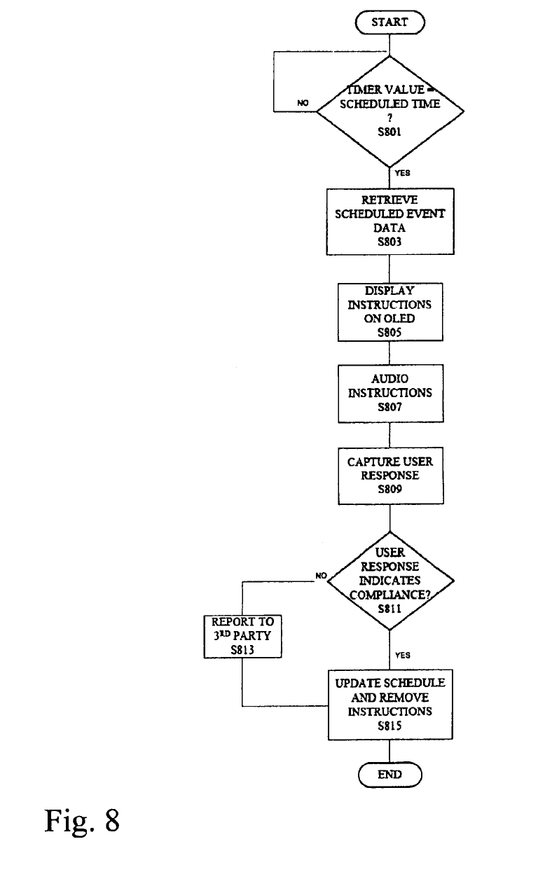

FIG. 8 is another flowchart that describes another preferred embodiment of the intelligent display dividing system and the TOLED architectural partition. At step S801 the controller waits for a scheduling input (e.g. time schedule). Once the input is received, the process proceeds to step S803 at which point the controller retrieves scheduled input data. The process then proceeds to step S805 to display instructions of the scheduled event data retrieved in step S803. The controller then sets audio instructions at step S807. At step S809 the controller waits for the user's response. Once the response has been received, the process proceeds to step S811, where the controller compares if the user's response indicates compliance with the previously scheduled input data. If not, the process then proceeds to step S813 where the controller is programmed to report a message to a predetermined third party. However, if the response indicates compliance, the process then proceeds to step S815 where the controller is programmed to update the schedule.

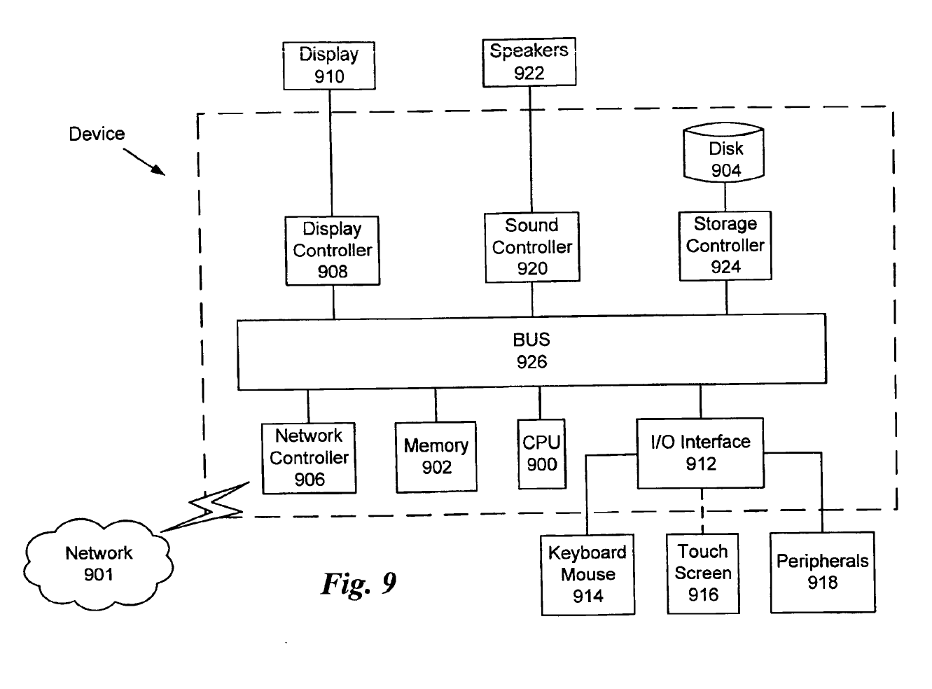

FIG. 9 is a block diagram for a hardware description of the processing circuitry 115 according to exemplary embodiments. The processing circuitry includes a CPU 900 which performs the processes described above. The process data and instructions may be stored in memory 902. These processes and instructions may also be stored on a storage medium disk 904 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the processing circuitry communicates, such as a server or computer, or a smart phone.

Further, the claimed advancements may be provided as a utility application, background daemon, or component of an operating system, or combination thereof, executing in conjunction with CPU 900 and an operating system such as Microsoft Windows 7, UNIX, Solaris, LINUX, Apple MAC-OS, Android and other systems known to those skilled in the art.

CPU 900 may be a Xenon or Core processor from Intel of America or an Opteron processor from AMD of America, or may be other processor types that would be recognized by one of ordinary skill in the art. Alternatively, the CPU 900 may be implemented on an FPGA, ASIC, PLD or using discrete logic circuits, as one of ordinary skill in the art would recognize. Further, CPU 900 may be implemented as multiple processors cooperatively working in parallel to perform the instructions of the inventive processes described above.

The processing circuitry in FIG. 9 also includes a network controller 906, such as an Intel Ethernet PRO network interface card from Intel Corporation of America, for interfacing with network 901. As can be appreciated, the network 901 can be a public network, such as the Internet, or a private network such as an LAN or WAN network, or any combination thereof and can also include PSTN or ISDN sub-networks. The network 901 can also be wired, such as an Ethernet network, or can be wireless such as a cellular network including EDGE, 3G and 4G wireless cellular systems. The wireless network can also be WiFi, Bluetooth, or any other wireless form of communication that is known.

The processing circuitry further includes a display controller 908, such as a NVIDIA GeForce GTX or Quadro graphics adaptor from NVIDIA Corporation of America for interfacing with display 910, such as a Hewlett Packard HPL2445w LCD monitor. A general purpose I/O interface 912 interfaces with a keyboard and/or mouse 914 as well as a touch screen panel 916 on or separate from display 910. General purpose I/O interface also connects to a variety of peripherals 918 including printers and scanners, such as an OfficeJet or DeskJet from Hewlett Packard.

A sound controller 920 is also provided in the processing circuitry, such as Sound Blaster X-Fi Titanium from Creative, to interface with speakers/microphone 922 thereby providing sounds and/or music.

The general purpose storage controller 924 connects the storage medium disk 904 with communication bus 926, which may be an ISA, EISA, VESA, PCI, or similar, for interconnecting all of the components of the processing circuitry. A description of the general features and functionality of the display 910, keyboard and/or mouse 914, as well as the display controller 908, storage controller 924, network controller 906, sound controller 920, and general purpose I/O interface 912 is omitted herein for brevity as these features are known.

Thus, the foregoing discussion discloses and describes merely exemplary embodiments of the present invention. As will be understood by those skilled in the art, the present invention may be embodied in other specific forms without departing from the spirit or essential characteristics thereof. Accordingly, the disclosure of the present invention is intended to be illustrative, but not limiting of the scope of the invention, as well as other claims. The disclosure, including any readily discernible variants of the teachings herein, define, in part, the scope of the foregoing claim terminology such that no inventive subject matter is dedicated to the public.

1. An intelligent display dividing system comprising:
a foldable, retractable partition including a flexible TOLED display screen configured to be deployed in an interior space, so as to divide the interior space into two separate spaces;
a controllable motor configured to controllably retract and deploy a translatory side of the foldable, retractable partition so as to controllably change between a folded state and a taut state, the foldable, retractable TOLED being visible as transparent from the interior space, when in the taut state;
a sensor configured to generate a control signal that actuates the controllable motor in response to detecting at least one of a user gesture and reception of a remote control signal; and
a processor having circuitry configured to respond to the control signal by actuating the controllable motor to automatically retract or deploy the foldable, retractable partition and automatically display a predetermined image from an image source on the flexible TOLED display screen when the foldable, retractable partition is deployed.

2. The system according to claim 1, further comprising:
a remote control configured to send the remote control signal to the sensor.

3. The system according to claim 2, wherein
the remote control signal is one of an Infra-red signal and a wireless RF signal.

4. The system according to claim 1, further comprising:
a non-transitory storage device configured to store at least one captured image as the predetermined image, a plurality of detected gesture patterns as predetermined gestures, and a plurality of remote control signals as predetermined signals.

5. The system according to claim 1, further comprising:
an imaging device configured to capture image data, and provide the image data to the processor for display on the flexible TOLED display screen.

6. The system according to claim 5, wherein the imaging device is further configured to capture video data as image data.

7. The system according to claim 4, wherein the circuitry is further programmed to,
cause the sensor to detect the user gesture,
compare, whether a detected user gesture corresponds to one of the predetermined gestures, and
when a correspondence exists, cause the motor to move the partition to a taut state and in response activate the flexible TOLED display screen,
receive image data from an imaging device,
determine if the image data corresponds to the predetermined image, and if there is a correspondence control the flexible TOLED display screen to display one of plurality of user interfaces;
compare, whether a detected gesture corresponds to one of the predetermined plurality of gestures associated with retracting the flexible TOLED display screen, and when a correspondence exists,
cause the motor to retract the foldable, retractable partition and deactivate the flexible TOLED display screen.

8. The system according to claim 7, wherein the circuitry is further programmed to respond to the control signal by controlling the flexible TOLED display screen to display one of the plurality of interfaces, and
cause the sensor to detect a height of a user and cause the motor to adjust a deployment amount of the foldable, flexible partition to a height that corresponds with the height of the user.

9. The system according to claim 1, wherein the flexible TOLED display screen is at least 1 m×1 m.

10. The system according to claim 1, wherein the flexible TOLED display screen is touch sensitive to receive user input via a user contacting the flexible TOLED display.

11. The system according to claim 1, further comprising:
a catch at a transitory side of the foldable, retractable partition that holds the partition taut when fully deployed and coupled to a receiving latch.

12. The system according to claim 11, wherein the catch is a movable magnetic catch that is configured to be moved in a controlled manner to import a ripple effect on the flexible TOLED display screen.

13. The system according to claim 5, further comprising:
another imaging device located exterior to the interior space and configured to capture image data, to be displayed on the foldable, retractable TOLED display so the foldable, retractable TOLED appears as a virtual window.

14. The system according to claim 2, wherein the remote control is a smart phone and executes a downloadable application to produce the remote control signal.

15. A method of operating an intelligent display dividing system, comprising:
detecting one of a gesture or a control signal;
operating a controllable motor in response to detecting a gesture or a control signal to deploy a foldable, retractable partition including a flexible TOLED display screen used to divide an interior space into two separate spaces;
activating the flexible TOLED display screen portion;
generating an image to be displayed on the TOLED display portion;
detecting another gesture or control signal; and
in response to selecting retracting the TOLED display portion and deactivating the intelligent display dividing system.

16. A non-transitory computer-readable medium including executable instructions, which when executed by circuitry, cause the circuitry to execute a process, comprising:
detecting one of a gesture or a control signal;
operating a controllable motor in response to detecting a gesture or a control signal to deploy a foldable, retractable partition including a flexible TOLED display screen used to cover a wall or to divide interior spaces;
activating the flexible TOLED display screen portion;
generating an image to be displayed on the TOLED display portion;
detecting another gesture or control signal and in response retracting the TOLED display portion and deactivating the intelligent display dividing system.
